(19) United States
(12) Patent Application Publication
(10) Pub. No.: US 2005/0058310 A1
(43) Pub. Date: Mar. 17, 2005

(54) Audio player with decorative sealed vessel

(76) Inventor: Vincent K. Lee, Taipei (TW)

Correspondence Address: BACON & THOMAS, PLLC, 625 SLATERS LANE, FOURTH FLOOR, ALEXANDRIA, VA, 22314, US

(21) Appl. No.: 10/836,251

(22) Filed: May 3, 2004

(30) Foreign Application Priority Data
Sep. 16, 2003 (TW) 092216603

(51) Int. Cl. H03G 11/00; H04R 1/02; H04B 1/00

(52) U.S. Cl. 381/124; 381/87; 381/395

(57) ABSTRACT

The present invention discloses a liquid ornament with an audio player comprising an audio player and a liquid ornament. The decorative sealed vessel is mounted in the through hole of the body of the audio player. The liquid ornament has at least one liquid and a decorative structure

### BACKGROUND OF THE INVENTION

1. Field of the Invention

The present invention relates to an audio player with a decorative sealed vessel, and the audio player can be a radio or a MP3 player.

2. Description of the Related Art

Several patents have been granted regarding the combination of a decorative sealed vessel with other objects to create a decorative effect; for example, in U.S. Pat. No. 6,380,926 several embodiments are disclosed, such as a cup having with a decorative sealed vessel, or a toothbrush box with a decorative sealed vessel.

However, no prior art discloses an audio player with a decorative sealed vessel. Audio players have been in use for over 20 years, and have become a necessary device for many people. Many design shapes for audio players are developed each year, but none of the designs contain decorative sealed vessels.

### SUMMARY OF THE INVENTION

A main objective of the present invention is to provide an audio player with a decorative sealed vessel, which causes the audio player seen more enjoyable and interesting. According to an embodiment of the present invention, the audio player has a through hole located properly, and the decorative sealed vessel is mounted in the through hole.

Another objective of the present invention is to provide an audio player with a decorative sealed vessel, and the decorative sealed vessel capable of moving automatically

In order to achieve the above mentioned objectives, the present invention, a decorative sealed vessel with an audio player comprises an audio player and a decorative sealed vessel. The decorative sealed vessel is mounted in the through hole of the body of the audio player. The decorative sealed vessel has at least one liquid and a decorative structure.

In order to cause the decorative sealed vessel to move automatically, a second magnet is mounted on the decorative structure, so that when the audio player provides a varying magnetic field, the decorative structure moves accordingly. The varying magnetic field can be provided by the electric motor or by an electromagnet.

Other objects, advantages, and novel features of the invention will become more apparent from the following detailed description when taken in conjunction with the accompanying drawings.

### BRIEF DESCRIPTION OF THE DRAWINGS

FIG. 1 illustrates a first embodiment according to the present invention.

FIG. 2 is an exploded view of the first embodiment according to the present invention.

FIG. 3 is a side view of the decorative sealed vessel according to the present invention.

FIG. 4 illustrates a second embodiment according to the present invention, and includes a partial cross-sectional drawing.

FIG. 5 is a side view of an electric motor shown in FIG. 4 according to the present invention.

FIG. 6 illustrates a third embodiment according to the present invention, and includes a partial cross-sectional drawing.

FIG. 7 illustrates of a fourth embodiment according to the present invention.

### DETAILED DESCRIPTION OF THE PREFERRED EMBODIMENT

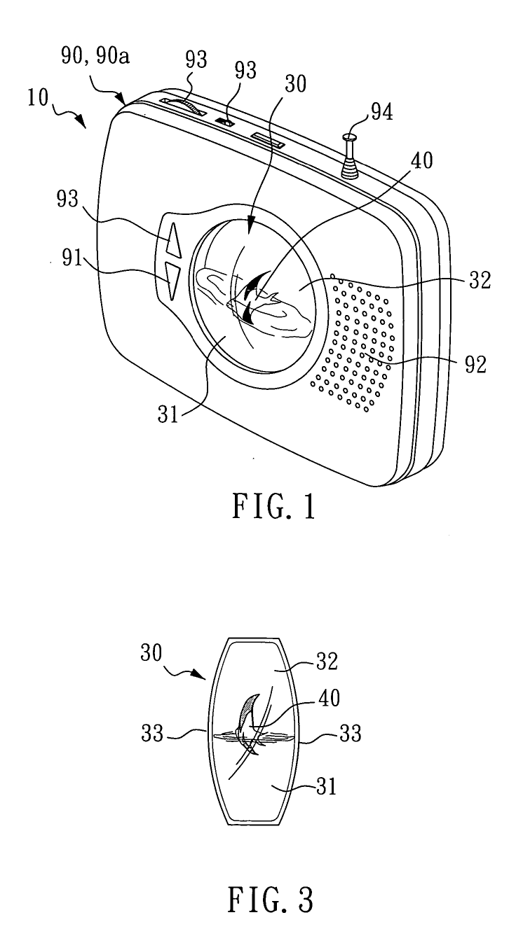

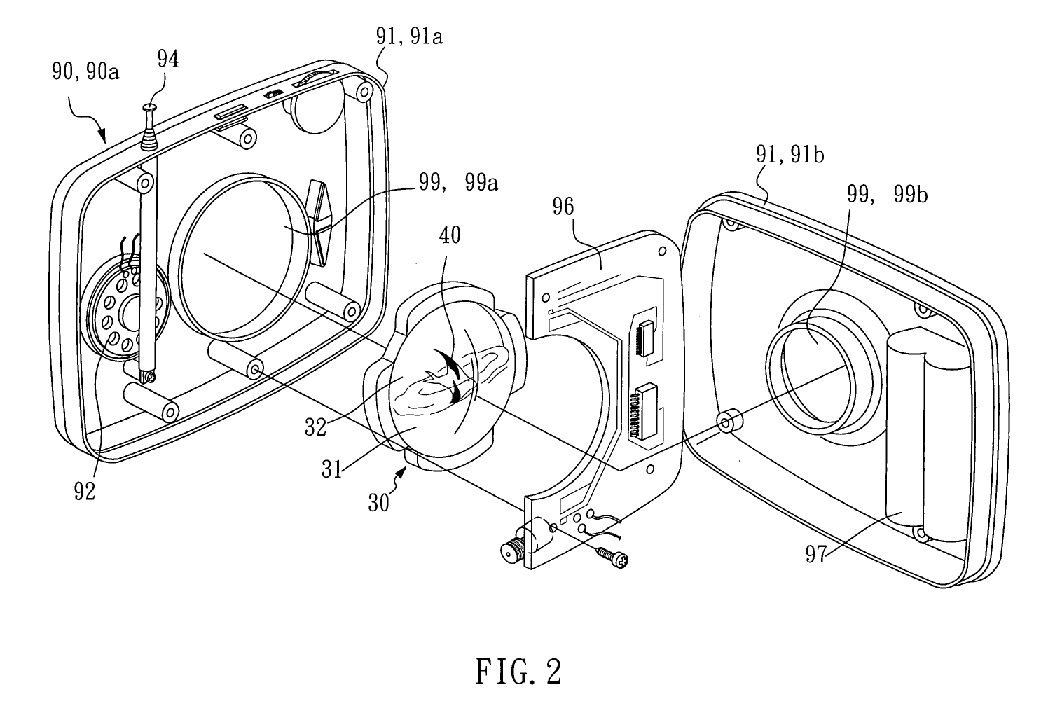

There will be four embodiments explained in following description. Please refer to FIG. 1 to FIG. 3. FIG. 1 illustrates a first embodiment according to the present invention. FIG. 2 is an exploded view of the first embodiment according to the present invention. FIG. 3 is a side view of the decorative sealed vessel according to the present invention. An audio player with a decorative sealed vessel 90 comprises an audio player 10 and a sealed vessel 30. In the first embodiment, the audio player 10 is a radio 90a, which comprises a body 91 (ex. composed by two housing 91a and 91b), a speaker 92 (or a headphone output hole, not shown), a plurality of control buttons 93, an antenna 94 and a circuit device 96 for playing an audio signal. Moreover, the radio 90a utilizes a battery 97 or an external power source to provide power to the circuit device 96. Since the audio player 10 (radio 90a) is a very well known product and also not the point of the present invention, there will be no further description for its feathers and structure.

The decorative sealed vessel 30 is combined with the body 91 of the audio player 10. The decorative sealed vessel 30 comprises a at least one liquid and a decorative structure 40. According to the embodiment, there are two liquids, a first liquid 31 and a second liquid 32. The second liquid 32 is less dense than the first liquid 31, and they usually have different colors. The decorative structure 40 is insoluble and floats between the first liquid 31 and the second liquid 32.

In this embodiment, the body 91 has a through hole 99 (composed by two through holes 99a and 99b), and the decorative sealed vessel 30 is mounted in the through hole 99. The decorative sealed vessel 30 has a raised arc surface 33 (as shown in FIG. 3) so a magnified effect can be shown on the decorative structure 40. Since the decorative sealed vessel 30 is mounted in the through hole 99, it can be saw from both sides of the audio player 10. Many methods may be used to combine the decorative sealed vessel 30 with the body 91, including the use of adhesives or clamping.

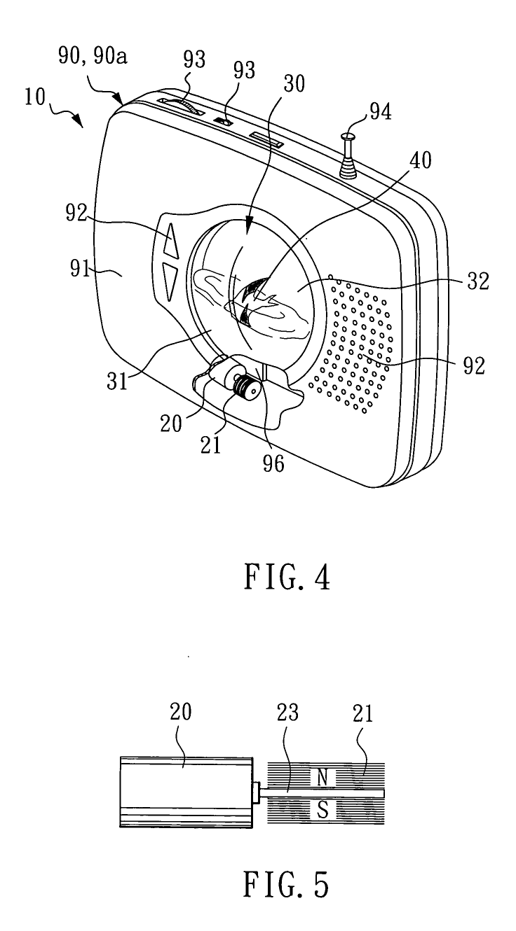

Please refer to FIG. 4. FIG. 4 illustrates a third embodiment according to the present invention, including a partial cross-sectional drawing. In this embodiment, the circuit device 96 further comprises an electric motor 20, and the electric motor 20 may be any device that can transfer the electrical power to mechanical power. The electric motor 20 may be any device that converts electrical power to mechanical power. For example, the electric motor 20 may be a common rotational-style motor, a motor for a clock, a solenoid, etc. Please refer to FIG. 5. FIG. 5 is a side view of the electric motor shown in FIG. 4 according to the present invention. A first magnet 21 is mounted on a shaft 23 (which is a transfer means) of the electric motor 20. Thus, the electric motor 20 rotates the first magnet 21 to generate a varying magnetic field. Many different mechanical designs may be employed to move the first magnet 21 in order to generate a varying magnetic field. The manner of moving the first magnet 21 could be actual rotation as mentioned above, or could also be an oscillatory movement, vibration, or other types of movement. The transfer means between the electric motor 20 and the first magnet 21 may be the shaft 23, but may also include gears, linkages, etc. Therefore, it is not necessary that the electric motor 20 and the first magnet 21 be directly connected, but simply that the electric motor 20 provides power to move the first magnet 21.

In this embodiment, a second magnet 41 is mounted on the decorative structure 40. The first magnet 21 is positioned around the decorative sealed vessel 30. Consequently, when the first magnet 21 moves, the second magnet 41 also moves, causing the decorative structure 40 to move accordingly. Because of the characteristics of the varying magnetic field and the liquid, the decorative structure 40, in fact, will tend to make unpredictable movements (shaking), and the first liquid 31 and the second liquid 32 will also shake accordingly.

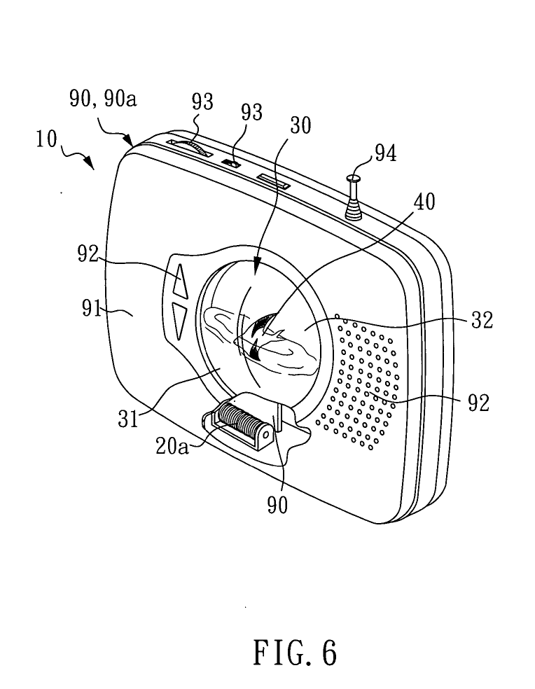

Please refer to FIG. 6. FIG. 6 illustrates a fourth embodiment according to the present invention, and includes a partial cross-sectional drawing. The major difference of the fourth embodiment is the use of an electromagnet 20a, instead of using the first magnet 21 and the electric motor 20 shown in the first embodiment. The electromagnet 20a is a standard electronics component, which generates a magnetic field when an electric current is provided (i.e. when the electric current passes through a coil, an electromagnet's major element, a magnetic field is generated). Therefore, it is easy to make the electromagnet 20a generate a varying magnetic field by providing the electromagnet 20a with a correspondingly varying electric current. For example, by changing the amount of current, or the direction of the current, a varying electric current is produced.

In the second embodiment and the third embodiment, the electrical power is provided to the electric motor 20 or the electromagnet 20a to generate a varying magnetic field, as mentioned above. The electric current provided to the electric motor 20 or the electromagnet 20a can be continuous, discontinuous, or provided under other pre-set conditions (for example, when the audio player 10 is turned on, or applying a current to the electric motor 20 or the electromagnet 20a based on a playing volume). The method of controlling the current supplied to the electric motor 20 or the electromagnet 20a is a very well known technique, there will be no more description.

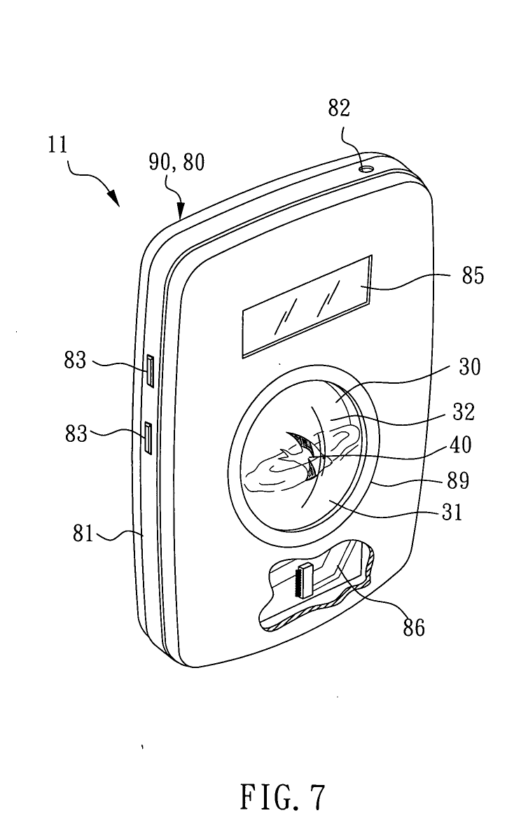

Please refer to FIG. 7. FIG. 7 illustrates a fourth embodiment according to the present invention. The audio player 10 is a MP3 player 80. The MP3 player 80 is very similar to the radio, the MP3 player 80 comprises a body 81, a headphone output hole 82, a plurality of control buttons 83, a displaying screen 85 and a circuit device 86. Similar to the first embodiment, the body 81 has a through hole 89 and the decorative sealed vessel 30 is mounted in the through hole 89. The purpose of the fourth embodiment is showing the audio player 10 can be other audio electric device such as a MP3 player, a CD player, a tape player (like a walkman).

Although the present invention has been explained in relation to its preferred embodiment, it is to be understood that many other possible modifications and variations can be made without departing from the spirit and scope of the invention as hereinafter claimed.

1. An audio player with a decorative sealed vessel comprises:
an audio player comprising a body and a circuit mechanism for playing audio signal, characterized in that the audio player further comprises:
a decorative sealed vessel comprising at least one liquid and at least one decorative structure being insoluble in the liquid, wherein the decorative sealed vessel is coupled with the body of the audio player.

2. The audio player with a decorative sealed vessel as claimed in claim 1, wherein the audio player is a radio.

3. The audio player with a decorative sealed vessel as claimed in claim 1, wherein the audio player is a MP3 player.

4. The audio player with a decorative sealed vessel as claimed in claim 1, wherein the audio player further comprises a through hole, and the decorative sealed vessel is embedded in the through hole.

5. The audio player with a decorative sealed vessel as claimed in claim 2, wherein the audio player further comprises a through hole, and the decorative sealed vessel is embedded in the through hole.

6. The audio player with a decorative sealed vessel as claimed in claim 3, wherein the audio player further comprises a through hole, and the decorative sealed vessel is embedded in the through hole.

7. The audio player with a decorative sealed vessel as claimed in claim 1, wherein the audio player further comprises:
a first magnet;
an electric motor for converting electrical power to mechanical
power so as to move the first magnet; and
the decorative structure further comprising a second magnetic;
wherein the first magnet is positioned around the decorative sealed vessel, and when the first magnet moves, the second magnet moves with the first magnet so that the decorative structure also moves accordingly.

8. The audio player with a decorative sealed vessel as claimed in claim 1, wherein the audio player further comprises:
an electromagnet for generating a varying magnetic field; and the decorative structure further comprises a second magnet;
wherein the electromagnet is positioned around the decorative sealed vessel and when the first magnet moves, the second magnet moves with the first magnet so that the decorative structure also moves accordingly.
